(19) United States
(12) Patent Application Publication
(10) Pub. No.: US 2010/0236620 A1
(43) Pub. Date: Sep. 23, 2010

(54) THIN FILM SOLAR CELL AND METHOD FOR PRODUCING THE SAME

(75) Inventors: Tsutomu NAKANISHI, Tokyo (JP); Eishi Tsutsumi, Kawasaki-shi (JP); Akira Fujimoto, Kawasaki-shi (JP); Kumi Masunaga, Kawasaki-shi (JP); Ryota Kitagawa, Tokyo (JP); Koji Asakawa, Kawasaki-shi (JP); Hideyuki Nishizawa, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Toshiba, Tokyo (JP)

(21) Appl. No.: 12/706,338

(22) Filed: Feb. 16, 2010

(30) Foreign Application Priority Data
Mar. 18, 2009 (JP) 2009-065928

(51) Int. Cl. H01L 31/0236; H01L 31/18

(52) U.S. Cl. 136/256; 438/61; 257/E31.13

(57) ABSTRACT

According to one aspect of the present invention, there is provided a thin film solar cell comprising a substrate, a photoelectric conversion layer formed on said substrate, said photoelectric conversion layer having a thickness of 1 μm or less, and said photoelectric conversion layer comprising a p-type semiconductor layer, an n-type semiconductor layer, and are i-type semiconductor layer placed between said p-type semiconductor layer and said n-type semiconductor layer, a light-incident side electrode layer formed on a light-incident surface of said photoelectric conversion layer and a counter electrode layer formed on the surface opposite to the light-incident surface. Said light-incident side electrode layer has plural openings bored though said layer, and the thickness thereof is in the range of 10 nm to 200 nm. Each of said openings occupies an area of 80 nm² to 0.8 μm². The opening ratio is in the range of 10% to 66%.

### CROSS-REFERENCE TO RELATED APPLICATIONS

This application is based upon and claims the benefit of priority from the prior Japanese Patent Application No. 2009-65928, filed on Mar. 18, 2009; the entire contents of which are incorporated herein by reference.

### BACKGROUND OF THE INVENTION

1. Field of the Invention

The present invention relates to a thin film solar cell excellent in conversion efficiency, and also relates to a method for producing that solar cell.

2. Background Art

As a photoelectric conversion device capable of converting solar light energy into electric energy, there has hitherto been known a thin film silicon solar cell utilizing silicon, which is rich in resource. A thin film silicon solar cell of pin-type laminate structure comprises a p-type silicon semi-conductor layer, an i-type silicon semiconductor layer and an n-type silicon semiconductor layer.

The thin film silicon solar cell comprises a photoelectric conversion layer mainly made of amorphous silicon semi-conductor, and hence the light-receiving area thereof can be easily expanded as compared with a crystalline silicon solar cell, which comprises a photoelectric conversion layer of crystalline silicon, and also the light-absorption coefficient thereof is larger than that of the crystalline silicon solar cell by approximately two orders of magnitude. The thin film silicon solar cell, therefore, has advantages that it can be thinned down to contribute for resource conservation and also that it is excellent in mass-productivity.

On the other hand, however, the thin film silicon solar cell has a disadvantage that it has lower conversion efficiency than the crystalline silicon solar cell. This is because carrier diffusion length in the amorphous silicon semiconductor is so short that carries excited in a depletion layer are readily recombined before they reach collector electrodes. Even if the photoelectric conversion layer is so thinned down as to avoid the recombination of carriers, the conversion layer thus thinned down cannot cause sufficient photo-excitation. Accordingly, in a thin film silicon solar cell generally used, the photoelectric conversion layer has a total thickness of approximately 0.3 μm to 0.6 μm, and it has been difficult to further thin down the layer while keeping high conversion efficiency.

Since microcrystalline silicon semiconductor has higher sensitivity in a long wavelength range than amorphous silicon semiconductor and further since the carrier diffusion length therein is longer than that in the amorphous silicon, the crystallite silicon is often used in the photoelectric conversion layer. However, the microcrystalline silicon is an indirect transition type semiconductor, and hence has a smaller absorption coefficient than the amorphous silicon. Accordingly, the photoelectric conversion layer of microcrystalline silicon needs to have a total thickness of 2 to 4 μm.

Meanwhile, solar cells are clean energy sources and hence are drawing attention of people as effective means for solving the environmental and energy problems in the future. Accordingly, demands for solar cells are expected to expand. In consideration that, as for the thin film silicon solar cell, it becomes one of the most important subjects to thin down the photoelectric conversion layer while keeping high energy-conversion efficiency, so as to contribute for resource conservation and to reduce the production cost.

The thin film silicon solar cell has another advantage that it can be made flexible if formed on a flexible substrate. Since the flexible solar cell can be laminated on a curved surface, various applications are expected. Further, it can be manu-factured according to a roll-to-roll process or to a stepping roll process, and is therefore suitable for mass-production.

However, since the flexible substrate generally has plasticity, membrane stress occurs in a thin amorphous or microcrystalline silicon film serving as the photoelectric conversion layer. The stress acts on the amorphous silicon film or on the microcrystalline silicon film as a compressive stress of 300 to 600 MPa or of 500 to 1000 MPa, respectively. As a result, even when no force is applied to the flexible substrate, the substrate is liable to curl so that the photoelectric conversion layer may be outside. This tendency to curl often causes troubles such as making handling in processes difficult and wrinkling on the flexible substrate.

To cope with the above problem, it is proposed (in, for example, JP-A 2004-56024(KOKAI)) that a thin layer having the same membrane stress as the photoelectric conversion layer is provided on the flexible substrate on the side opposite to the conversion layer side. Further, it is also proposed (in, for example, JP-A 1994-280026(KOKAI)) that the flexible substrate itself be beforehand subjected to tension or compressive stress.

In the former method, however, there is a fear that the solar cell may have such an increased total thickness to impair the flexibility. On the other hand, in the latter method, the stress or tension beforehand applied to the substrate is often relaxed in thermal processes of the method and hence it may result in failure to obtain the aimed effect. This means that there is a fear of lowering the throughput. In order to prevent the flexible substrate from curling, it is necessary to thin down the photoelectric conversion layer while keeping high conversion efficiency. However, it has been difficult for conventional techniques to solve this problem.

### SUMMARY OF THE INVENTION

According to one aspect of the present invention, there is provided a thin film solar cell comprising:

a substrate,

a photoelectric conversion layer formed on said substrate, said photoelectric conversion layer having a thickness of 1 μm or less, and said photoelectric conversion layer comprising a p-type semiconductor layer, an n-type semiconductor layer, and an i-type semiconductor layer placed between said p-type semiconductor layer and said n-type semiconductor layer,

a light-incident side electrode layer formed on a light-incident surface of said photoelectric conversion layer, and

a counter electrode layer formed on the surface opposite to the light-incident surface; wherein

said light-incident side electrode layer has plural openings bored though said light-incident side electrode layer, and the thickness thereof is in the range of 10 nm to 200 nm,

each of said openings occupies an area of 80 nm² to 0.8 μm², and

the opening ratio is in the range of 10% to 66%, said opening ratio being defined as the ratio of the total area of said openings based on that of said light-incident side electrode layer.

According to still another aspect of the present invention, there is provided a method for producing the above solar cell, comprising:

forming said counter electrode layer on said substrate,

forming said photoelectric conversion layer on said counter electrode layer, and

forming said light-incident side electrode layer on said photoelectric conversion layer;

wherein the step of forming said light-incident side electrode layer comprises:

forming a thin metal layer,

preparing a stamper whose surface has a fine relief pattern corresponding to the shape of the light-incident side electrode layer intended to be formed,

transferring a resist pattern onto at least a part of said thin metal layer by use of said stamper, and

etching said thin metal layer by use of said resist pattern as an etching mask, to form a light-incident side electrode layer having fine openings.

### BRIEF DESCRIPTION OF THE DRAWINGS

FIG. 1 is an overview of a thin film solar cell according to the first embodiment.

FIG. 2 is a schematic sectional view of a thin film solar cell according to the first embodiment.

FIG. 3 is a schematic sectional view illustrating the working principle of a thin film solar cell according to the first embodiment.

FIG. 4 is conceptual diagrams illustrating the working principle of a thin film solar cell according to the first embodiment.

FIG. 5 is a graph showing distribution of enhanced electric fields at the edges of the openings.

FIG. 6 is a graph showing a relation between the diameter of the openings and the electric field strength.

FIG. 7 is schematic plane views illustrating a light-incident side electrode layer according to the first embodiment.

FIG. 8 is conceptual diagrams illustrating a process for producing a thin film solar cell according to the first embodiment.

FIG. 9 is conceptual diagrams illustrating a process for forming a light-incident side electrode layer by use of nano-imprint method according to the first embodiment.

FIG. 10 is conceptual diagrams illustrating a process for forming a light-incident side electrode layer by use of nano-imprint method according to the first embodiment.

FIG. 11 is a schematic sectional view of a thin film solar cell according to the second embodiment.

### DETAILED DESCRIPTION OF THE INVENTION

### First Embodiment

The first embodiment of the present invention is explained below by referring to the attached drawings.

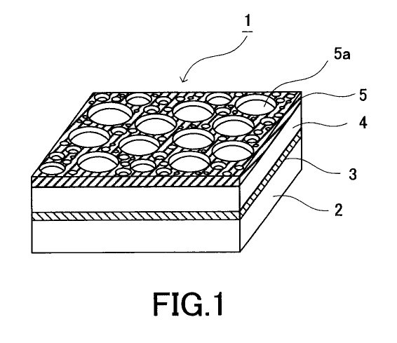

FIG. 1 schematically shows the structure of a thin film solar cell according to the first embodiment of the present invention. Needless to say, the structure shown in FIG. 1 is only a typical example for helping to understand the embodiment of the present invention, and accordingly it by no means restricts the present invention.

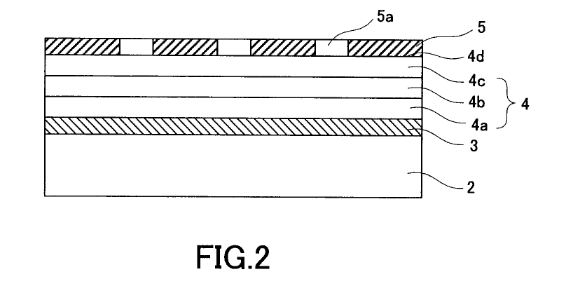

As shown in FIGS. 1 and 2, the thin film solar cell 1 mainly comprises a substrate 2, a counter electrode layer 3 formed on the substrate 2, a photoelectric conversion layer 4 formed on the counter electrode layer 3, and a light-incident side electrode layer 5 formed on the photoelectric conversion layer 4. The thin film solar cell 1 according to the first embodiment is of a substrate type in which incident light comes not through the substrate 2 but directly into the photoelectric conversion layer 4 from the side of the light-incident side electrode layer 5.

There is no particular restriction on the substrate 2 as long as it can function as a support of the layers constituting the thin film solar cell 1, and hence known rigid or flexible substrates are usable. For example, the rigid substrate may be an insulating substrate. Examples of the insulating rigid substrate include: glass substrate, quartz substrate, silicon substrate; substrates of oxides such as oxides of silicon (Si), aluminum (Al), germanium (Ge), magnesium (Mg) and beryllium (Be); substrates of nitrides such as silicon nitride (Si₃N₄) and boron nitride (BN); and substrates of ceramics such as silicon carbide (SiC). Among them, a glass substrate is preferred from the viewpoints that it can be obtained at low-cost and has high flatness in a large area. The substrate may be a metal substrate. Examples of the metal substrate include substrates of aluminum (Al), chromium (Cr), cobalt (Co), copper (Cu), iron (Fe), zinc (Zn), titanium (Ti) and lead (Pb). If the substrate is made of a metal, it is necessary to form an insulating layer of, for example, silicon dioxide or silicon nitride, so as to prevent the substrate from short-circuiting to the substrate-side electrode provided thereon.

Examples of the flexible substrates include substrates of plastics such as polyamide, polyimide, liquid crystal polymer, fluorocarbon resins, polyethylene naphthalate (PEN), poly-ethylene terephthalate (PET), polyetherimide (PEI), polyether-sulfone (PES), polystyrene (PS), polymethyl methacrylate (PMMA), and polycarbonate (PC). In view of processing-heat resistance, particularly preferred are polyimide and polyethylene terephthalate.

Although not particularly shown in FIGS. 1 and 2, a barrier layer may be formed on the substrate 2 if there is a fear that metal impurities may diffuse from the substrate 2 to deteriorate the photoelectric conversion layer 4. Further, a buffer layer may be provided to improve adhesion onto the substrate 2.

There is no particular restriction on the thickness of the substrate 2 as long as it can function as a support of the layers constituting the thin film solar cell 1. In the case where the substrate is a rigid substrate, the thickness thereof is preferably 500 μm or more from the viewpoint of mechanical strength but is preferably 5 mm or less from the viewpoint of lightening the solar cell. In the case where the substrate is a flexible substrate, the thickness thereof is preferably in the range of 5 μm to 350 μm.

The counter electrode layer 3 can additionally have a function of reflecting light not absorbed by the photoelectric conversion layer. In consideration of that, the counter electrode layer 3 is preferably made of a metal having high reflectivity. Examples of the metal include aluminum (Al), silver (Ag), gold (Au) and platinum (Pt). Among them, preferred is aluminum or silver, which has high reflectivity. For the purpose of improving adhesion and heat-resistance, the counter electrode 3 may be made of an alloy obtained by adding other metals into the above metals. For example, an alloy of silver and palladium (Pd) can improve the heat-resistance.

If the counter electrode layer 3 is too thin, it often transmits light to the substrate 2 side. Accordingly, the counter electrode layer 3 preferably has a thickness of 10 nm or more. On the other hand, from the viewpoints of shortening the manufacturing time and of lightening the solar cell, the thickness is preferably 1 μm or less.

Further, in order to absorb light in the photoelectric conversion layer 4, the counter electrode layer 3 may have a rough surface. The roughness may be controlled by conditions for forming the counter electrode layer 3. In a different way, for example, it is also possible to make the surface of the substrate 2 beforehand so rough that the counter electrode layer 3 formed thereon may have a rough surface.

The counter electrode layer 3 not necessarily consists of a single metal layer, and may have a layered structure for ensuring both functions of reflecting light and of serving as an electrode. For example, after a silver layer is formed, a trans-parent electroconductive oxide such as tin-doped indium oxide (ITO), tin oxide (SnO₂), zinc oxide (ZnO) or aluminum-doped zinc oxide (AZO) is accumulated thereon to form a two-layered structure. In that case, the thickness of the transparent electroconductive layer can be so controlled that reflection of light at a particular wavelength may be enhanced by interference effect.

The photoelectric conversion layer 4 comprises at least a p-type semiconductor layer 4a, an i-type undoped semi-conductor layer 4b, and an n-type semiconductor layer 4c. The i-type semiconductor layer 4b is placed between the p-type semiconductor layer 4a and the n-type semiconductor layer 4c, to form a pin-structure. In the pin-structure, excited carriers generated in the i-type semiconductor layer 4b are drifted by the action of a built-in field induced by the n-type and p-type semiconductor layers 4a and 4c placed on the top and bottom of the i-type semiconductor layer 4b, and consequently the conversion layer generates photo-electromotive force.

The i-type semiconductor layer 4b can be made of a semiconductor material such as amorphous silicon, microcrystalline silicon, amorphous silicon-germanium or amorphous silicon-carbon. If those materials of the i-type semiconductor layer 4b are doped with boron (B) or the like, they are usable as the materials of the p-type semiconductor layer 4a. If the above materials of the i-type semiconductor layer 4b are doped with phosphorus (P) or the like, they are usable as the materials of the n-type semiconductor layer 4c.

The photoelectric conversion layer 4 has a thickness of 1 μm or less. Each of the p-type and n-type semiconductor layers 4a and 4c preferably has a thickness of 5 nm or more so that they can induce a built-in field by which carriers generated in the i-type semiconductor layer 4b are drifted. On the other hand, however, in order to reduce light absorption of each layer, each of the p-type and n-type semiconductor layers 4a and 4c preferably has a thickness of 100 nm or less. The i-type semi-conductor layer 4b preferably has a thickness of 10 nm to 500 nm.

For the purpose of keeping the photoelectric conversion layer 4 from deterioration caused by sunlight, a transparent and electroconductive barrier layer may be formed thereon. The barrier layer can be made of, for example, a transparent electroconductive oxide such as titanium oxide or tin oxide.

The light-incident side electrode layer 5 is formed on a light-incident surface 4d of the photoelectric conversion layer 4. The light-incident side electrode layer 5 is preferably made of a metal on which local enhanced electric fields can be induced near openings 5a, as described later. The material of the electrode layer 5 also preferably absorbs light in a small amount in the wavelength range intended to be used. Examples of the material include aluminum (Al), silver (Ag), gold (Au), platinum (Pt), nickel (Ni), cobalt (Co), chromium (Cr), copper (Cu), titanium (Ti), and alloys thereof. On the top surface of the light-incident side electrode layer 5, a collector electrode may be further provided.

The light-incident side electrode layer 5 has plural openings 5a bored through the layer 5 in the thickness direction. There is no particular restriction on the shapes of the openings, and hence they may be in any shapes such as circles, ovals, polyhedrons or other closed curves.

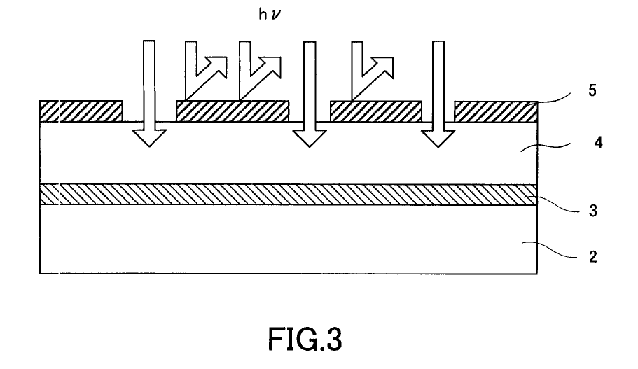

In the present embodiment, the light-incident side electrode layer 5 having a mesh structure can give enough electric field-enhancement effect to increase photoelectric conversion efficiency. Because of this effect, even if the photo-electric conversion layer 4 is thinned down, a solar cell excellent in photoelectric conversion efficiency can be obtained. Further, the light-incident side electrode layer 5 can be easily and economically produced. For illustrating the working principle of a thin film solar cell according to the present embodiment, conceptual drawing is shown in FIGS. 3.

When light comes from the side of the light-incident side electrode layer 5 as illustrated in FIG. 3, since the light-incident side electrode layer 5 is made of metal, the photoelectric conversion layer 4 in the areas covered with the metal of the electrode layer 5 reflects the light coming to those areas not to transmit the light. As a result, the light penetrates only through the openings 5a and reaches the photoelectric conversion layer 4 in the areas not covered. This means that the photoelectric conversion layer 4 generally receives light in an amount corresponding to the area ratio of the openings 5a based on the whole electrode 5. The photoelectric conversion layer 4 is therefore generally thought to generate photo-electromotive force in proportion to the amount of the received light.

Surprisingly, however, the present inventors have actually found that the light-incident side electrode layer 5 having the particular structure enables to increase the electric current more than expected from the amount of light received by the photoelectric conversion layer 4.

This phenomenon can be presumed to be caused by the following mechanism.

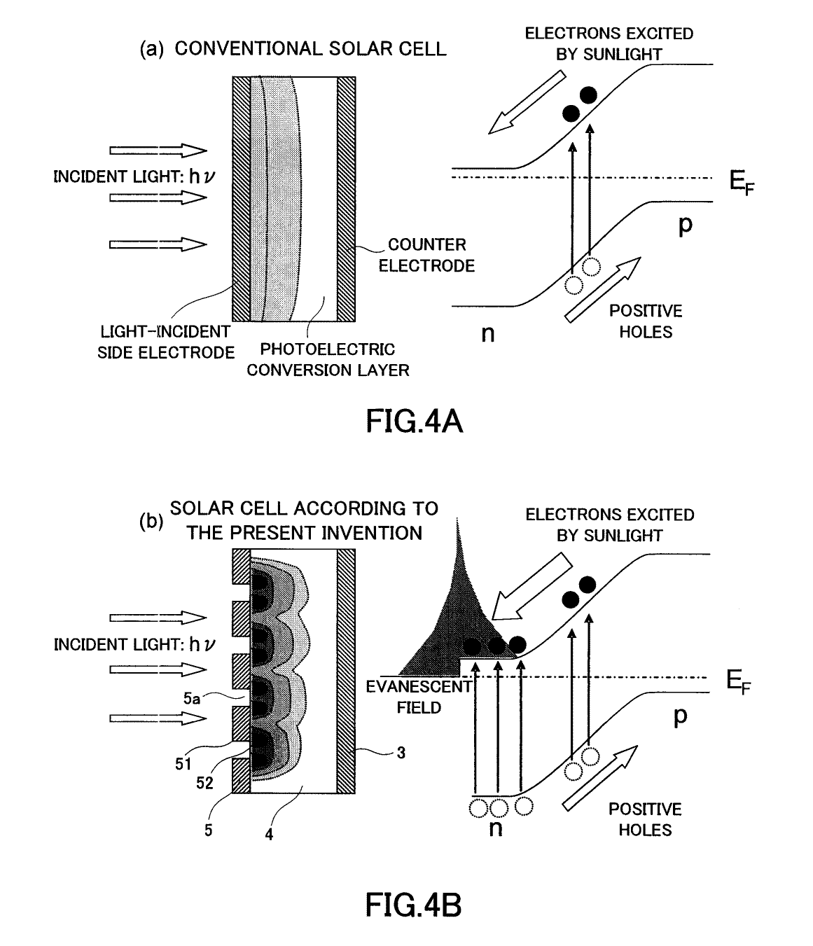

It is already known that, when a thin metal film having fine openings is exposed to light, surface plasmons are excited under the condition that the openings have diameters corresponding to the wavelength of the incident light. FIG. 4A is conceptual diagrams illustrating mechanism by which carries are excited according to a conventional solar cell, and FIG. 4B is conceptual diagrams illustrating mechanism by which excited carries increase near the light-incident side electrode according to the present invention.

When a thin metal film receives light, free electrons in the film are induced to oscillate horizontally. However, the oscillation of free electrons is not uniform in the thickness direction. The nearer to the surface irradiated with the light the free electrons are positioned, the more easily they are oscillated. Accordingly, in the light-incident side electrode layer 5 in the form of a thin metal film, the free electrons are liable to localize on the upper side 51 at the edges, so that electric fields along the thickness are generated at the edges. As a result, the electric fields extend into the photoelectric conversion layer 4, to generate enhanced electric fields (local enhanced electric fields) at areas 52 right under the edges of the light-incident side electrode layer 5, namely, right under the peripheries of the openings 5a.

As described above, the thin film solar cell 1 of the present embodiment comprises a mesh metal electrode as the light-incident side electrode layer 5, so that light passing through the openings 5a can be photoelectrically converted and further so that electric fields near the edges of the openings 5a can be enhanced. In this way, a great amount of carriers are presumed to be excited to increase the conversion efficiency. In other words, according to the present embodiment, the photoelectric conversion is promoted even by light coming to the metal part of the light-incident side electrode layer 5, namely, even by light not reaching the photoelectric conversion layer 4.

Since the light-incident side electrode layer 5 is a mesh metal electrode, many carriers near the electrode layer 5 are excited on the basis of the above mechanism. Accordingly, even if the photoelectric conversion layer 4 is thinned down, it is possible to obtain excellent conversion efficiency.

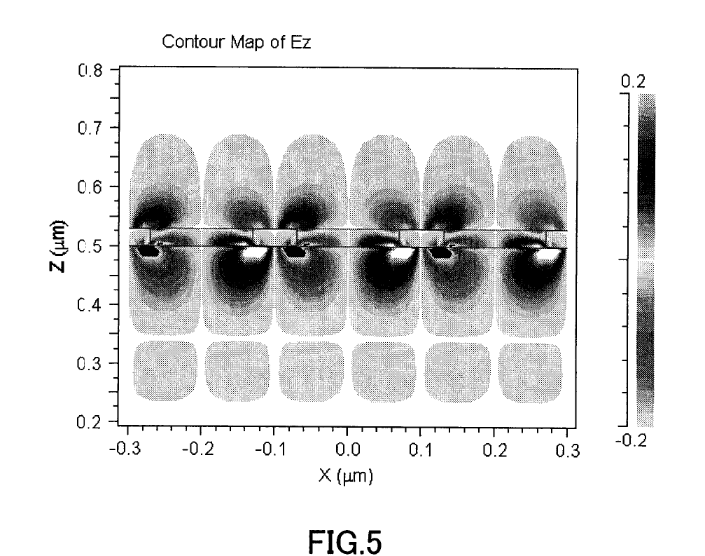

With respect to the thin film solar cell according to an embodiment of the present invention, the strength of electric field was calculated by use of FDTD (finite difference time domain) method. The calculation was performed under the assumptions that the photoelectric conversion layer is made of Si, that the light-incident side electrode is a 30 nm thick aluminum film provided with openings having an opening period of 200 nm and an opening diameter of 140 nm, and that light of 1000 nm wavelength is applied onto the light-incident side electrode side. FIG. 5 shows strength distribution of electric fields perpendicular to the photoelectric conversion layer. FIG. 5 reveals that electric fields are enhanced at the edges of the light-incident side electrode.

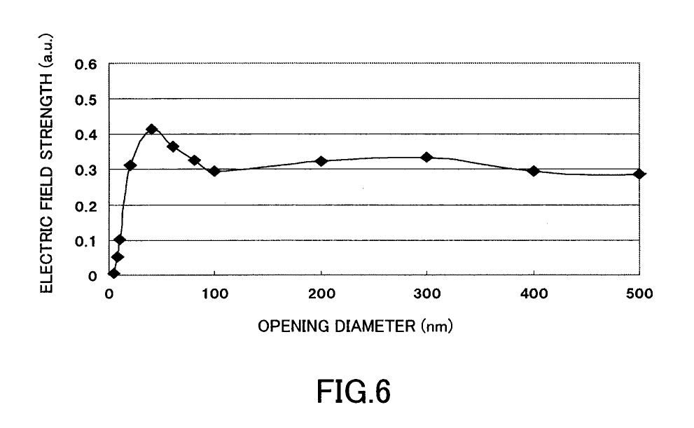

Further, it was also calculated how the distance between two adjacent openings, namely, the length of unbroken light-incident side electrode part between two adjacent openings, is related to the strength of local electric fields at the edges of the electrode. The result is shown in FIG. 6. The result reveals that the electric field strength has a peak in a particular range of the distance between two adjacent openings. This is because, if the minimum distance among the openings is less than 10 nm in average, alternating electric fields appearing along the thickness at both ends of each electrode part are cancelled out by each other and hence are incapable of enhancing the electric field. On the other hand, if the minimum distance is more than 200 nm in average, the above alternating electric fields do not interact with each other and hence the electric field has constant strength. Further, in order that the electrode may have sufficient electroconductivity, the minimum distance among the openings needs to be 10 nm or more. Accordingly, in the light-incident side electrode of the present invention, the minimum distance among the openings is preferably 10 nm to 200 nm, more preferably 30 nm to 100 nm.

In order to obtain the effect of the present embodiment efficiently on the whole light-incident side surface, the density of the openings 5a (opening density) is preferably large because the local enhanced electric field is generated at the edge of each opening, regardless of arrangement of the openings 5a. This means that, in view of only the opening density, the opening diameter is preferably small. As described above, however, if the diameter is 10 nm or less, the electric fields enhanced near the openings 5a are remarkably lowered. Accordingly, the plural openings 5a formed on the light-incident side electrode layer 5 are required to have diameters (opening diameters) of 10 nm or more. On the other hand, however, if the opening diameters are too large, the opening density is lowered. From this viewpoint, the opening diameters need to be 1.0 μm or less. In the cases including the case where the openings 5a are circles in shape, each of the openings 5a needs to occupy an area of 80 nm² to 0.8 μm². Since the electric field strength at the edge of each opening 5a is maximized, the diameter of each opening 5a is preferably 40 nm to 200 nm and the area thereof is preferably 1000 nm² to 0.03 μm².

The opening ratio, which is the ratio of the total area of the openings 5a based on that of the light-incident side electrode layer 5, needs to be 10% to 66%, preferably 25% to 66%. If the opening ratio is less than 10%, the density of the openings 5a is too low to enhance the electric field. On the other hand, however, if it is more than 66%, the distance among the openings 5a is too short to ensure the electro-conductivity of the light-incident side electrode layer 5.

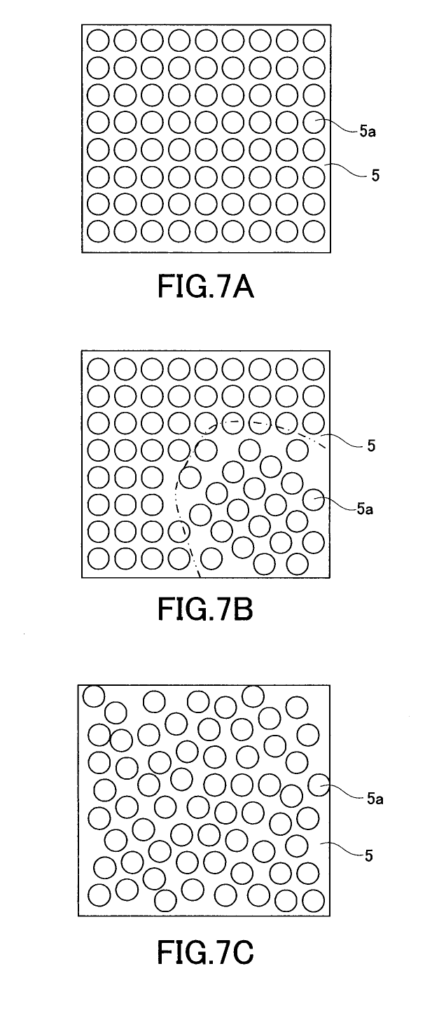

As described above, the effect of the present embodiment is derived from the local enhanced electric fields generated near the edges of the openings 5a. There is no particular restriction on the arrangement of the plural openings 5a bored through the light-incident side electrode layer 5, as long as they have diameters and areas satisfying the above conditions. Accordingly, the openings 5a may be arranged in a completely periodic structure (FIG. 7A) in which the arrangement of the openings 5a is uniform. Further, they may form a microdomain structure (FIG. 7B) in which the openings 5a are arranged periodically like poly-crystals in the plane to form plural domains but in which the domains are oriented in the plane independently of each other. Furthermore, the openings 5a may be arranged randomly to form a random structure (FIG. 7C). Even in the case where the openings 5a are arranged in an at least partly periodic structure such as the completely periodic structure or the microdomain structure, there is no particular restriction on the arrangement as long as the structure has periodicity in the plane. The structure, therefore, may be a triangle or rectangle arrangement.

The light-incident side electrode layer 5 needs to have a thickness of 10 nm to 200 nm, preferably 10 nm to 100 nm. If the thickness is less than 10 nm, the light-incident side electrode layer 5 has insufficient electroconductivity. On the other hand, if the thickness of the electrode layer 5 is more than 200 nm, the photoelectric conversion layer 4 is incapable of benefiting from the electric field-enhancement effect sufficiently. Since the effect of the present invention cannot be obtained in that case, that case is unfavorable.

As described above, the local enhanced electric fields are generated owing to the structure of the light-incident side electrode layer 5. This electric field-enhancement effect works on the i-type semiconductor layer 4b, and thereby the photo-electric conversion efficiency is improved. The i-type semi-conductor layer 4b is, therefore, necessarily placed within a short distance from the light-incident side electrode layer 5. Accordingly, the i-type semiconductor layer 4b is at least partly positioned within a distance of preferably 500 nm or less, most preferably 200 nm or less from the contact surface between the light-incident side electrode layer 5 and the photoelectric conversion layer 4. When the light-incident side electrode layer 5 is exposed to sunlight, the local enhanced electric fields are generated. However, in accordance with increasing the distance from the light-incident side electrode layer 5, those electric fields rapidly attenuate. Although depending on the material of the electrode layer 5, the attenuation distance is almost in the range of a few tens of nanometers to 500 nm. If the i-type semiconductor layer 4b is positioned apart from the light-incident side electrode layer 5 in a distance of more than 500 nm, the local enhanced electric fields are less effective in exciting the carriers and hence there is a fear that the effect of the invention cannot be obtained.

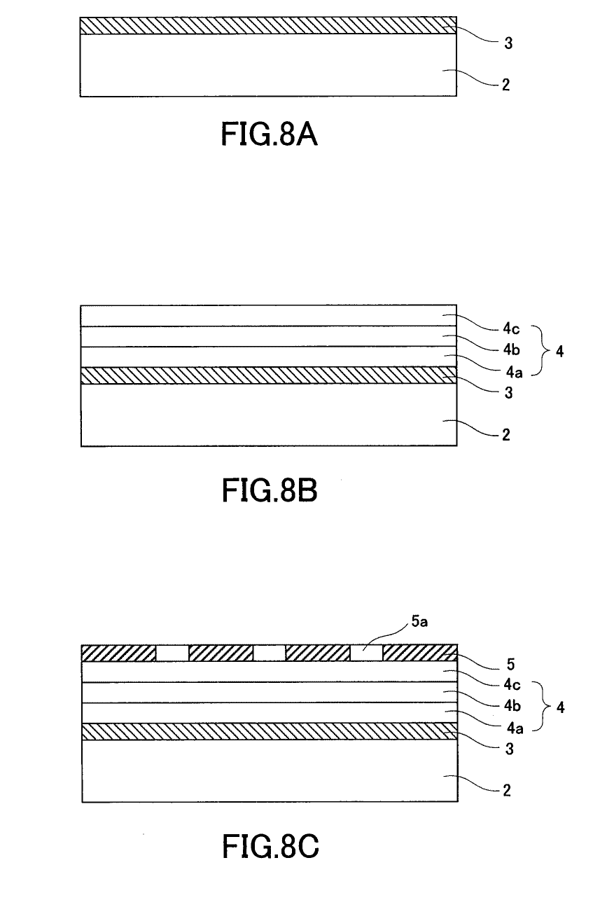

Subsequently, the method for producing a thin film solar cell 1 of the present embodiment is described below. FIG. 8 is conceptual diagrams illustrating a method for producing a thin film solar cell 1 of the present embodiment.

First, as shown in FIG. 8A, a counter electrode 3 is formed on a substrate 2. There is no particular restriction on the method for forming the counter electrode 3, and hence various methods, such as a vacuum vapor-deposition method, a sputtering method and a laser abrasion method, are employable. Among them, the sputtering method is preferred because the counter electrode 3 formed by sputtering is excellent in adhesion to the substrate 2.

After the counter electrode 3 is formed, a photoelectric conversion layer 4 is formed thereon, as shown in FIG. 8B. For forming an i-type semiconductor layer 4b in the photo-electric conversion layer 4, various film-forming methods generally used can be employed. Among the methods, the plasma CVD method is preferred because a large and uniform layer can be formed. For example, a silicon thin layer can be formed from source gases such as chain or cyclic silane compounds. Examples of the silane compounds include SiH₄, SiF₄, (SiF₂)₆, (SiF₂)₆, (SIF₂)₄, Si₂F₆, Si₃F₈, SiHF₃, SiH₂F₂, Si₂H₂F₄, Si₂H₃F₃, SiCl₄, (SiCl₂)₅, SiBr₄, (SiBr₂)₅, SiCl₆, SiHCl₃, SiHBr₂, SiH₂Cl₂, and SiCl₃F₃. In consideration of dangling bond ends, additive gases such as H₂ and the like may be incorporated in the material gases. Further, it is also possible to incorporate germanium substances such as chain germane, germanium halide, cyclic germane, and organic germanium compounds.

The plasma CVD method is also preferably used in the same manner as described above to form a p-type semi-conductor layer 4a because it can produce the layer continuously. For forming the p-type semiconductor layer 4a, additive gases such as boron substances can be added into the above source gases of the i-type semiconductor layer 4b to prepare those of the p-type semiconductor layer 4a. Examples of the additive gases include BF₃, B₂H₆, B₄H₁₀, B₅H₉, B₅H₁₀, B(CH₃)₃, B(C₂H₅)₃ and B₆H₁₂.

Also for forming an n-type semiconductor layer 4c, the plasma CVD method is preferably used in the same manner as described above because it can produce the layer continuously. For forming the n-type semiconductor layer 4c, additive gases such as nitrogen or phosphorus substances can be added into the above source gases of the i-type semiconductor layer 4b to prepare those of the n-type semiconductor layer 4c. Examples of the additive gases include N₂, NH₃, N₂H₅N₃, N₂H₄, NH₄N₃, PH₃, P(OCH₃)₃, P(OC₂H₅)₃, P(C₃H₇)₃, P(OC₄H₉)₃, P(CH₃)₃, P(C₂H₅)₃, P(C₃H₇)₃, P(C₄H₉)₃, P(OCH₃)₃, P(OC₂H₅)₃, P(OC₃H₇)₃, P(OC₄H₉)₃, P(SCN)₃, and P₂H₄.

After the photoelectric conversion layer 4 is formed, a light-incident side electrode layer 5 having openings 5a is formed thereon, as shown in FIG. 8C.

Various known fine fabrication techniques can be employed to form the light-incident side electrode layer 5. For example, the material of the electrode layer 5 is deposited on the whole surface of the substrate by use of the sputtering method or the plasma CVD method, and then the plural openings 5a are bored by use of fine fabrication techniques such as photo-lithography, electron beam lithography and nano-imprinting. Since the openings 5a bored through the light-incident side electrode layer 5 are arranged in a very fine pattern, the nano-imprint process is preferred in view of fabrication cost.

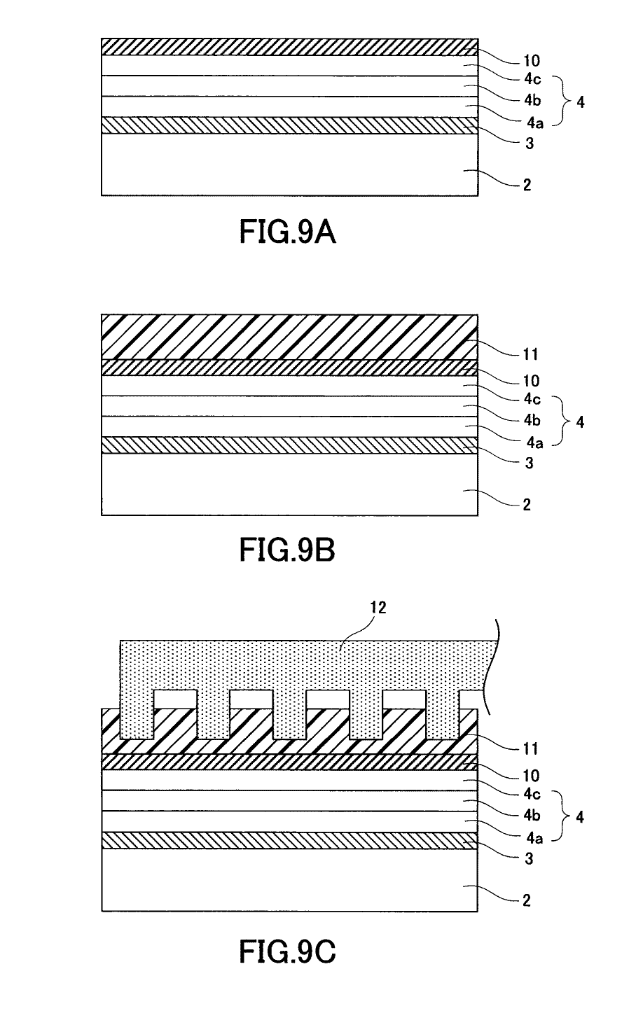

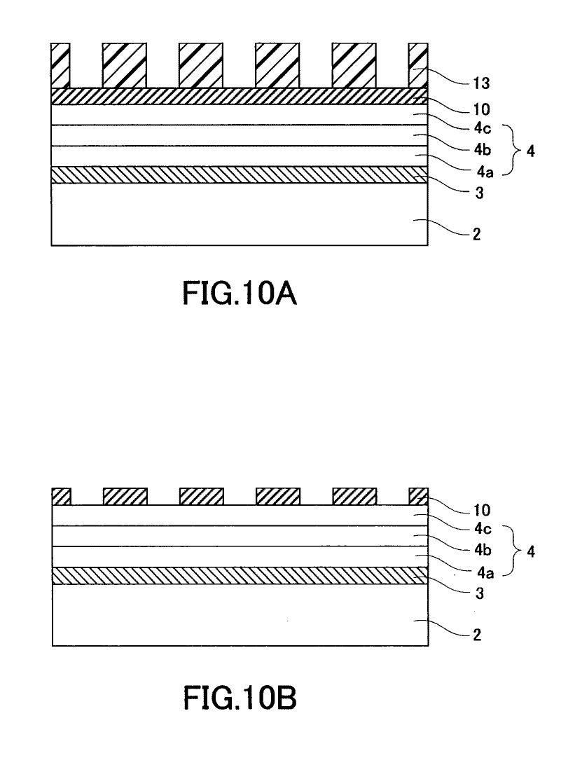

The method for forming the light-incident side electrode layer 5 according to the nano-imprint process is explained below. FIGS. 9 and 10 are conceptual diagrams illustrating a method for forming the light-incident side electrode layer 5 by nano-imprinting.

First, as shown in FIG. 9A, a thin metal layer 10 intended to be the light-incident side electrode layer 5 is formed on the photoelectric conversion layer 4, for example, by sputtering. Subsequently, as shown in FIG. 9B, a resist layer 11 is formed on the thin metal layer 10, for example, by coating. After the resist layer 11 is formed, a fine relief pattern is transferred onto the resist layer 11 by use of a stamper 12 beforehand prepared, as shown in FIG. 9C. As shown in FIG. 10A, residual films remaining on the bottom of the pattern are then removed to form a resist pattern 13. The fine relief pattern beforehand formed on a surface of the stamper 12 is corresponding to the shape of the light-incident side electrode layer 5 intended to be formed. Thereafter, the thin metal layer 10 is etched by use of the resist pattern 13 as an etching mask, to obtain a light-incident side electrode layer 5 having fine openings 5a.

The stamper 12 can be prepared by use of the latest nano-fabrication techniques. However, a fabrication method utilizing a micro-phase separation pattern of block copolymer or a method utilizing a self-assembled pattern of fine particles is preferably adopted because such method enables to prepare a stamper having a large surface at low production cost.

In the case where the substrate 2 is a flexible substrate, the thin film solar cell can be manufactured according to a roll-to-roll process or to a stepping roll process because those processes enable to realize high throughput. In the roll-to-roll process, the flexible substrate is continuously conveyed through deposition chambers in each of which each layer is continuously formed thereon. On the other hand, in the stepping roll process, the flexible substrate is conveyed into and stopped in each deposition chamber in which each layer is formed thereon, and then conveyed into the next chamber.

In a different way, the openings 5a may be formed according to the following methods, such as

(A) a method comprising:

coating a resist on a thin metal film intended to be an electrode, to form a resist layer;

forming a particle monolayer of fine particles on the resist layer,

etching the resist layer by use of the particle monolayer as an etching mask, to form a resist pattern having openings corresponding to the aimed fine openings,

filling the openings in the resist pattern with inorganic substance, to form a reverse pattern mask, and

etching the thin metal film by use of the reverse pattern mask, to form fine openings; and

(B) a method comprising:

coating a composition containing a block copolymer on a thin metal film intended to be an electrode, to form a block copolymer layer,

forming microdomains of the block copolymer in a dot pattern, and

etching the thin metal film by use of the dot pattern of the formed microdomains, to bore fine openings.

Further, the surface electrode can be also formed in another manner. For example, before the thin metal layer is formed, a pattern of resist or of inorganic substance is formed on the photoelectric conversion layer 4. After that, metals are accumulated on spaces in the pattern by vapor deposition or the like to form the surface electrode.

Thus, according to the method of the present embodiment for producing a thin film solar cell, the thin film solar cell 1 can be obtained in high throughput.

### Second Embodiment

The second embodiment of the present invention is explained below by referring to the attached drawings.

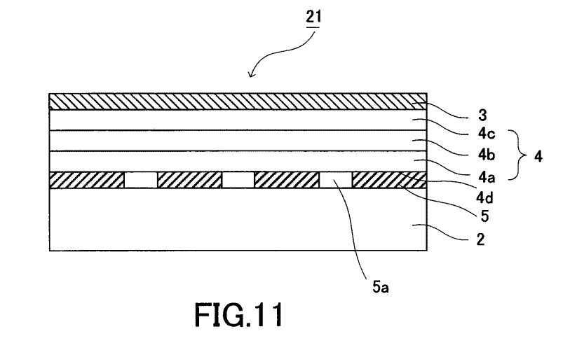

FIG. 11 schematically shows the structure of a thin film solar cell according to the second embodiment of the present invention. As shown in FIG. 11, the thin film solar cell 21 of the present embodiment has a supersubstrate type structure in which the photoelectric conversion layer 4 is exposed to light through the substrate 2.

The thin film solar cell 21 has almost the same structure as the thin film solar cell 1 except that the counter electrode 3 is placed on the photoelectric conversion layer 4 and that the light-incident side electrode layer 5 is placed between the substrate 2 and the photoelectric conversion layer 4. Except for those points, the thin film solar cell 21 is the same as the solar cell 1. Detailed explanation of the solar cell 21 is therefore omitted.

Since comprising the light-incident side electrode layer 5 having the openings 5a, the thin film solar cell of the present embodiment can also have the same effect as that of the first embodiment.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

### EXAMPLES

The present invention is further explained by the following examples, in which amorphous silicon solar cells according to the present invention were manufactured and the conversion efficiencies thereof were compared with those of comparative amorphous silicon solar cells.

### Samples

### Example 1

First, an Al layer of 500 nm thickness was formed on a 30 mm square quartz substrate by sputtering, to provide a counter electrode layer. The sputtering was performed in a chamber beforehand evacuated to 10⁻⁵ Pa by use of an Al target under the conditions of: Ar gas flow rate: 30 sccm, DC electric power: 200 W and pressure: 0.67 Pa.

The sample thus treated was placed in a CVD apparatus and then the chamber was evacuated to 10⁻⁵ Pa. Subsequently, while gases of SiH₄, H₂ and 5% PH₃ diluted with H₂ in the flow rates of 30 sccm, 300 sccm and 10 sccm, respectively, were introduced into the chamber, a n-type amorphous silicon layer having a thickness of 20 nm was formed under the conditions of: substrate temperature: 300° C., pressure: 200 Pa and RF

electric power: 10 W.

After that, the chamber was again evacuated to 10^{˜}5 Pa. Subsequently, while gases of SiH₄ and H₂ in the flow rates of 30 sccm and 300 sccm, respectively, were introduced into the chamber, an i-type amorphous silicon layer having a thickness of 300 nm was formed under the conditions of: RF electric power: 30 W and pressure: 200 Pa.

Further, the chamber was yet again evacuated to 10⁻⁵ Pa. Subsequently, while gases of SiH₄, H₂ and 5% BF₃ diluted with H₂ in the flow rates of 2 sccm, 300 sccm and 20 sccm, respectively, were introduced into the chamber, a p-type amorphous silicon layer having a thickness of 20 nm was formed under the conditions of: RF electric power: 10 W and pressure: 200 Pa. Thus, a photoelectric conversion layer having a pin-laminate structure was obtained.

After the photoelectric conversion layer was thus formed, another Al layer of 50 nm thickness was formed thereon to provide a light-incident side electrode layer by use of an Al target under the conditions of: Ar gas flow rate: 30 sccm, DC electric power: 100 W and pressure: 5 Pa.

Thereafter, on the Al layer intended to be a light-incident side electrode layer, a resist was coated in a thickness of 140 nm. The substrate was then put on a press platform of a nano-imprint apparatus, and a stamper was placed so that the stamper surface might be in contact with the resist.

Subsequently, imprinting was carried out for 1 minute at a substrate temperature of 125° C. under a stamping strength of 20 kgf.

The stamper used in the above step had a 25 mm square with dot pattern whose dot period, dot height, dot size and dot area ratio were 200 nm, 200 nm, 130 nm and 40%, respectively, and was beforehand produced in the following manner.

First, a resist layer having a thickness of 320 nm was formed on a 4 inch square quartz substrate by spin-coating, and then annealed to be hard-baked at 250° C. under N₂ atmosphere for 1 hour. In the hard baking procedure, the resist layer was so thermally hardened that the thickness thereof was reduced to 240 nm.

Independently, an ethyl lactate dispersion containing 4.5 wt % of silica particles having a mean particle diameter of 200 nm was mixed with trimethylol propane triacylate, which was a multi-functional acrylic monomer, in the same amount as the silica particles to prepare a coating dispersion. The coating dispersion was spin-coated on the above substrate to form a particle monolayer of the silica particles, and then annealed at 150° C. under N₂ atmosphere for 1 hour to thermally harden the acrylic monomer and thereby to fix the particle monolayer of the silica particles on the acrylic resin.

The obtained substrate having the particle monolayer was placed on a dry-etching apparatus and etched under the conditions of: O₂ flow rate: 30 sccm, pressure: 1.3 Pa and RF power: 100 W, so as to remove the acrylic resin. The substrate was further etched under the conditions of: CF₄ flow rate: 30 sccm, pressure: 1.3 Pa and RF power: 100 W, so that the silica particles were shaved until the size thereof was reduced to 130 nm. After the gas was changed to O₂, the substrate was furthermore etched by use of the silica particles as an etching mask under the conditions of: O₂ flow rate: 30 sccm, pressure: 0.3 Pa and RF power: 100 W, so that the arrangement of the particle monolayer was transferred onto the underlying resist layer and therefore so that the quartz substrate was partly bared. The substrate was yet further subjected to etching by use of the formed resist pattern as a mask under the conditions of: CF₄ flow rate: 10 sccm, CHF₃ flow rate: 20 sccm, pressure: 1.3 Pa and RF power: 100 W, so that the quartz substrate was etched in a depth of 200 nm.

Subsequently, the masking resist was removed by O₂ ashing, followed by piranha clean. After the surface thus fabricated was covered with a protective sheet, the substrate was cut into 25 mm square pieces to obtain a quartz stamper. The surface of the quartz stamper was spin-coated with perfluoro-polyether as a release agent, and then subjected to baking at 60° C. for 2 hours on a hot-plate. Thus, a stamper for nano-imprint was obtained.

After the nano-imprinting procedure was completed, the substrate was left until the substrate temperature was cooled to 90° C. Thereafter, the applied stamping pressure was released. When the stamper was released, it was found that the pattern of openings was transferred on the resist layer. The obtained sample was subjected to etching under the conditions of: O₂ flow rate: 30 sccm, pressure: 0.3 Pa, and RF power: 100 W, so as to remove residual films remaining on the bottom of the pattern. Subsequently, the Al layer was etched under the conditions of Cl₂ flow rate: 2.5 sccm, Ar flow rate: 25 sccm, pressure: 0.67 Pa, and RF power: 150 W, so as to form plural openings on the light-incident side electrode layer. Finally, the masking resist was removed by O₂ ashing, to obtain an amorphous silicon solar cell of Example 1.

### Example 2

The procedure of Example 1 was repeated except that the thickness of the i-type amorphous silicon layer was changed into 200 nm, to obtain an amorphous silicon solar cell similar to the solar cell of Example 1.

### Example 3

The procedure of Example 1 was repeated except that the thickness of the i-type amorphous silicon layer was changed into 100 nm, to obtain an amorphous silicon solar cell similar to the solar cell of Example 1.

### Comparative Example 1

The procedure of Example 1 was repeated except that the light-incident side electrode layer was changed into a 100 nm thick ITO layer having no openings, to obtain an amorphous silicon solar cell similar to the solar cell of Example 1. The ITO layer was formed by sputtering by use of an ITO target under the conditions of: Ar gas flow rate: 60 sccm, O₂ gas flow rate: 2 sccm, substrate temperature: room temperature and DC electric power: 200 W.

### Comparative Example 2

The procedure of Example 2 was repeated except that the light-incident side electrode layer was changed into a 100 nm thick ITO layer having no openings, to obtain an amorphous silicon solar cell similar to the solar cell of Example 2. The ITO layer was formed by sputtering by use of an ITO target under the conditions of: Ar gas flow rate: 60 sccm, O₂ gas flow rate: 2 sccm, substrate temperature: room temperature and DC electric power: 200 W.

### Comparative Example 3

The procedure of Example 3 was repeated except that the light-incident side electrode layer was changed into a 100 nm thick ITO layer having no openings, to obtain an amorphous silicon solar cell similar to the solar cell of Example 3. The ITO layer was formed by sputtering by use of an ITO target under the conditions of: Ar gas flow rate: 60 sccm, O₂ gas flow rate: 2 sccm, substrate temperature: room temperature and DC electric power: 200 W.

### (Evaluation)

Each of the solar cells obtained in Examples 1 to 3 and Comparative Examples 1 to 3 was exposed to pseudo-sunlight of AM 1.5, and thereby the properties thereof at room temperature were evaluated by means of a solar simulator.

### (Results)

With respect to the conversion efficiency of the produced solar cells, the ratio of Example 1 to Comparative Example 1 was found to be 1.12. The ratio of Example 2 to Comparative Example 2 was found to be 1.15, and that of Example 3 to Comparative Example 3 was found to be 1.23. These results verified that each solar cell of the present invention kept high conversion efficiency even if photoelectric conversion layer was thinned down.

In the same manner as described above, other type amorphous silicon solar cells according to the present invention were manufactured and the conversion efficiencies thereof were compared with those of comparative amorphous silicon solar Cells.

### (Samples)

### Example 4

A thin film amorphous silicon solar cell of the present invention was manufactured by use of a flexible substrate according to a roll-to-roll process. The flexible substrate was a polyimide substrate having a width of 10 cm, a length of 15 m and a thickness of 50 μm.

On the flexible substrate, an Al layer of 100 nm thickness was formed in a DC sputtering apparatus, to provide a counter electrode layer. The substrate was then wound up around a bobbin, and placed in a winding-off housing. The substrate was partly pulled out and set to be tightened from the winding-off housing to a winding-up housing through deposition chambers. Thereafter, each deposition chamber was evacuated.

While the reduced pressure was kept in each chamber, source gases are introduced and the inner pressure in each chamber was kept at the predetermined pressure. The bobbin in the winding-up housing was rotated so that the flexible substrate continuously moved toward the winding-up housing at a constant speed of 100 cm/min. While the flexible substrate was thus conveyed, n-type, i-type and p-type amorphous silicon layers were successively formed in the chambers according to the plasma CVD method in the following manners.

The n-type amorphous silicon layer was formed in a thickness of 20 nm under the conditions of: SiH₄ flow rate: 150 sccm, H₂ flow rate: 1800 sccm, PH₃ flow rate: 15 sccm, pressure: 140 Pa, substrate temperature: 300° C. and RF power: W. The i-type amorphous silicon layer was formed in a thickness of 200 nm under the conditions of: SiH₄ flow rate: 150 sccm, H₂ flow rate: 1800 sccm, pressure: 140 Pa, substrate temperature: 250° C. and RF power: 600 W. The p-type amorphous silicon layer was formed in a thickness of 20 nm under the conditions of: SiH₄ flow rate: 150 sccm, H₂ flow rate: 1800 sccm, BF₃ flow rate: 20 sccm, pressure: 140 Pa, substrate temperature: 300° C. and RF power: 20 W.

After all the flexible substrate was wound up in the winding-up housing, the chambers were cooled to room temperature. Air was leaked into the whole apparatus, and then the substrate was taken out. Subsequently, an Al layer having a thickness of 50 nm was formed on the substrate to provide a light-incident side electrode layer, and cut into 100 mm square pieces to obtain a flexible solar cell.

Thereafter, a resist was coated and a resist pattern was formed thereon by means of a thermal imprinting apparatus according to a roll-to-roll process. The thermal imprinting apparatus was equipped with a stamper for roll-to-roll imprint. The stamper was produced in the following manner.

In the same way as in Example 1, a dot pattern whose dot period, dot height, dot size and dot area ratio were 200 nm, 200 nm, 130 nm and 40%, respectively, was formed on a 100 mm square quartz substrate to produce a 100 mm square quartz stamper. On the other hand, on another 100 mm square quartz substrate, a resist was spin-coated in a thickness of 140 nm. In a nano-imprinting apparatus, the above stamper was so placed that the patterned surface thereof might be in contact with the resist layer, and imprinting was carried out for 1 minute at a substrate temperature of 125° C. under a stamping strength of 100 kgf. After the substrate temperature was cooled to 90° C., the applied stamping pressure was released. When the stamper was released, it was found that the pattern of openings was transferred onto the resist layer. The obtained sample was subjected to etching under the conditions of: O₂ flow rate: 30 sccm, pressure: 0.3 Pa and RF power: 100 W, so as to remove residual films remaining on the bottom of the pattern. The sample was further subjected to etching by use of the formed resist pattern as a mask under the conditions of: CF₄ flow rate: 10 sccm, CHF₃ flow rate: 20 sccm, pressure: 1.3 Pa and RF power: 100 W, so that the quartz substrate was etched in a depth of 200 nm. Finally, the masking resist was removed by O₂ ashing, followed by piranha clean. Thus obtained was a quartz substrate provided with a pattern reverse to the dot pattern of the stamper produced first. In the reverse pattern, the opening period, opening depth, opening size and opening area ratio were 200 nm, 200 nm, 130 nm and 40%, respectively.

On the quartz substrate thus provided with the opening pattern, a Ni layer having a thickness of 50 nm was formed in a DC sputtering apparatus so that the surface of the quartz substrate might be electroconductive. After that, a Ni electroformed layer having a thickness of 5 μm was formed according to Ni-electroforming. The Ni electroformed layer was then peeled from the substrate to obtain a 100 mm square Ni stamper. The obtained Ni stamper was laminated on a cylindrical core roller of 100 mm width and 100 mm circumference, to obtain a stamper for roll-to-roll imprint.

The above prepared stamper was used to perform nano-imprinting, followed by dry-etching, to form a light-incident side electrode layer having plural openings.

Finally, the masking resist was removed by O₂ ashing, to obtain an amorphous silicon solar cell of Example 4.

### Example 5

The procedure of Example 4 was repeated except that the thickness of the i-type amorphous silicon layer was changed into 100 nm, to obtain an amorphous silicon solar cell similar to the solar cell of Example 4.

### Comparative Example 4

The procedure of Example 4 was repeated except that the light-incident side electrode layer was changed into a 100 nm thick ITO layer having no openings, to obtain an amorphous silicon solar cell similar to the solar cell of Example 4. The ITO layer was formed by sputtering by use of an ITO target under the conditions of: Ar gas flow rate: 60 sccm, O₂ gas flow rate: 2 sccm, substrate temperature and DC electric power: 200 W.

### Comparative Example 5

The procedure of Example 5 was repeated except that the light-incident side electrode layer was changed into a 100 nm thick ITO layer having no openings, to obtain an amorphous silicon solar cell similar to the solar cell of Example 5. The ITO layer was formed by sputtering by use of an ITO target under the conditions of: Ar gas flow rate: 60 sccm, O₂ gas flow rate: 2 sccm, substrate temperature: room temperature and DC electric power: 200 W.

### (Evaluation)

Each of the solar cells obtained in Examples 4, 5 and Comparative Examples 4, 5 was exposed to pseudo-sunlight of AM 1.5, and thereby the properties thereof at room temperature were evaluated by means of a solar simulator.

### (Results)

With respect to the conversion efficiency of the produced solar cells, the ratio of Example 4 to Comparative Example 4 was found to be 1.12. The ratio of Example 5 to Comparative Example 5 was found to be 1.24. These results verified that each solar cell of the present invention kept high conversion efficiency even if photoelectric conversion layer was thinned down.

1. A thin film solar cell comprising:
a substrate,
a photoelectric conversion layer formed on said substrate, said photoelectric conversion layer having a thickness of 1 μm or less, and said photoelectric conversion layer comprising a p-type semiconductor layer, an n-type semiconductor layer, and an i-type semiconductor layer placed between said p-type semiconductor layer and said n-type semiconductor layer,
a light-incident side electrode layer formed on a light-incident surface of said photoelectric conversion layer, and
a counter electrode layer formed on the surface opposite to the light-incident surface; wherein
said light-incident side electrode layer has plural openings bored though said light-incident side electrode layer, and the thickness thereof is in the range of 10 nm to 200 nm,
each of said openings occupies an area of 80 nm² to 0.8 μm², and
the opening ratio is in the range of 10% to 66%, said opening ratio being defined as the ratio of the total area of said openings based on that of said light-incident side electrode layer.

2. The cell according to claim 1, wherein said i-type semiconductor layer is at least partly positioned within a distance of 500 nm from the contact surface between said light-incident side electrode layer and said photoelectric conversion layer.

3. The cell according to claim 1, wherein the average distance among said openings is in the range of 10 nm to 200 nm.

4. The cell according to claim 1, wherein said light-incident side electrode layer is made of a material selected from the group consisting of aluminum, silver, gold, platinum, nickel, cobalt, chromium, copper, titanium and alloys thereof.

5. The cell according to claim 1, wherein said i-type semiconductor layer has a thickness of 10 nm to 500 nm.

6. The cell according to claim 1, wherein said counter electrode layer is made of a material selected from the group consisting of aluminum, silver, gold, and platinum.

7. The cell according to claim 1, wherein said counter electrode layer is positioned between said substrate and said photoelectric conversion layer.

8. The cell according to claim 1, wherein said light-incident side electrode layer is positioned between said substrate and said photoelectric conversion layer.

9. The cell according to claim 1, wherein said counter electrode layer has a rough surface.

10. The cell according to claim 1, wherein said photoelectric conversion layer comprises at least one material selected from the group consisting of amorphous silicon, microcrystalline silicon, amorphous silicon-carbon, and amorphous silicon-germanium.

11. The cell according to claim 1, wherein said substrate is made of a material selected from the group consisting of glass, quartz, and silicon.

12. The cell according to claim 1, wherein said substrate is a flexible substrate and is made of a material selected from the group consisting of polyamide, polyamide imide, liquid crystal polymer, polyethylene naphthalate, polyethylene terephthalate, polyetherimide, polyethersulfone, polystyrene, and poly-carbonate.

13. A method for producing the cell according to claim 1, comprising:
forming said counter electrode layer on said substrate,
forming said photoelectric conversion layer on said counter electrode layer, and
forming said light-incident side electrode layer on said photoelectric conversion layer;
wherein the step of forming said light-incident side electrode layer comprises:
forming a thin metal layer,
preparing a stamper whose surface has a fine relief pattern corresponding to the shape of the light-incident side electrode layer intended to be formed,
transferring a resist pattern onto at least a part of said thin metal layer by use of said stamper, and
etching said thin metal layer by use of said resist pattern as an etching mask, to form a light-incident side electrode layer having fine openings.

14. The method according to claim 13; wherein said substrate is a flexible substrate, and at least one of said counter electrode layer, said photoelectric conversion layer and said light-incident side electrode layer is formed according to a roll-to-roll process or to a stepping roll process.
